(19) United States
(12) Patent Application Publication
(10) Pub. No.: US 2007/0258220 A1
(43) Pub. Date: Nov. 8, 2007

(54) Multiple mode micro memory card

(76) Inventors: Li-Pai Chen, Taipei City (TW); Ming-Dar Chen, Hsinchu City (TW); Hsiang-An Hsieh, Keelung City (TW); Jui-Bin Hwan, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/382,057

(22) Filed: May 8, 2006

(51) Int. Cl. H05K 5/00

(52) U.S. Cl. 361/730

(57) ABSTRACT

A micro memory card includes a first housing having a first thickness and a first width; a first device connector formed on an end of the first housing, the first device connector conforming to a first device connection standard and allowing access to memory of the micro memory card by a device compatible with the first device connection standard; a second housing having a second thickness and a second width, the second housing being integrally joined with the first housing; and a second device connector formed on an end of the second housing at an opposite end of the micro memory card from the first device connector, the second device connector conforming to a second device connection standard and allowing access to memory of the micro memory card by a device compatible with the second device connection standard.

### BACKGROUND OF THE INVENTION

1. Field of the Invention

The present invention relates to a micro memory card, and more particularly, to a micro memory card capable of operating in multiple modes.

2. Description of the Prior Art

As personal electronic devices become smaller and more sophisticated, the need for small sized memory cards becomes greater. As a result, micro sized flash memory cards have entered the market, and are used for miniature electronic devices that require swappable memory cards.

Please refer to FIGS. 1 and 2. FIG. 1 is a front view of a MMCmicro™ memory card 10 according to the prior art. FIG. 2 is a front view of a microSD™ memory card 20 according to the prior art. Both the MMCmicro memory card 10 and the microSD memory card 20 are considered to be micro-sized flash memory cards. Unfortunately, the MMCmicro memory card 10 must be read through a MMCmicro socket, and cannot be read by a microSD socket. The same problem exists for the microSD memory card 20, which cannot be ready by a MMCmicro socket.

Therefore, although the MMCmicro memory card 10 and the microSD memory card 20 have a similar size, their incompatibility causes problems for users, who must ensure that memory cards and sockets match each other.

### SUMMARY OF THE INVENTION

It is therefore an objective of the claimed invention to provide a micro memory card being compatible with both MMCmicro sockets and microSD sockets in order to solve the above-mentioned problems.

According to an exemplary embodiment of the claimed invention, a micro memory card is disclosed. The micro memory card includes a first housing having a first thickness and a first width; a first device connector formed on an end of the first housing, the first device connector conforming to a first device connection standard and allowing access to memory of the micro memory card by a device compatible with the first device connection standard; a second housing having a second thickness and a second width different from the first thickness and the first width of the first housing, the second housing being integrally joined with the first housing; and a second device connector formed on an end of the second housing at an opposite end of the micro memory card from the first device connector, the second device connector conforming to a second device connection standard and allowing access to memory of the micro memory card by a device compatible with the second device connection standard.

It is an advantage that the claimed micro memory card conforms to both the first and second device connection standards. In this way, the micro memory card can be utilized in three different types of sockets including a socket conforming to the first device connection standard, a socket conforming to the second device connection standard, and a socket that can receive a memory card conforming to both of the first and second connection standards.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a front view of a MMCmicro™ memory card according to the prior art.

FIG. 2 is a front view of a microSD™ memory card according to the prior art.

FIG. 3 is a front view of a multiple mode micro memory card according to the present invention.

FIG. 4 is a perspective front view of the multiple mode micro memory card.

FIG. 5 is a perspective rear view of the multiple mode micro memory card.

FIG. 6 and FIG. 7 are front and rear views of the multiple mode micro memory card.

FIG. 8 is a view of the top edge of the multiple mode micro memory card as shown in FIG. 6.

FIG. 9 is a view of the bottom edge of the multiple mode micro memory card as shown in FIG. 6.

FIG. 10 and FIG. 11 are left and right side views of the multiple mode micro memory card as shown in FIG. 6.

FIG. 12 is a rear view of the multiple mode micro memory card showing pad numbers for the first contact pads and the second contact pads.

FIG. 13 is a table describing the functions of contact pads on the multiple mode micro memory card when the multiple mode micro memory card is operated in different modes.

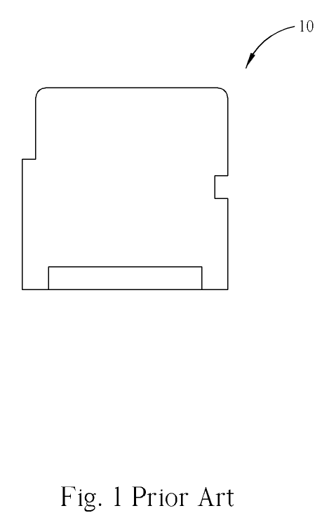

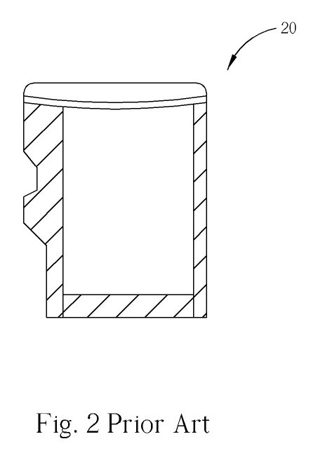

### DETAILED DESCRIPTION

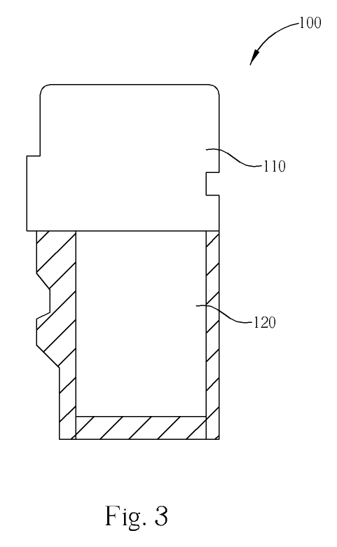

Please refer to FIG. 3. FIG. 3 is a front view of a multiple mode micro memory card 100 according to the present invention. The multiple mode micro memory card 100 contains a first housing 110 integrally joined with a second housing 120 to form an integrated housing. The first housing 110 conforms to the MMCmicro memory card standard and the second housing 120 conforms to the microSD memory card standard. In addition, the multiple mode micro memory card 100 creates a new memory card standard that utilizes both the first housing 110 and the second housing 120 for reading and writing data. As a result, the multiple mode micro memory card 100 is compatible with three different micro memory card form factors: the MMCmicro memory card standard, the microSD memory card standard, and the form factor of the new multiple mode micro memory card 100.

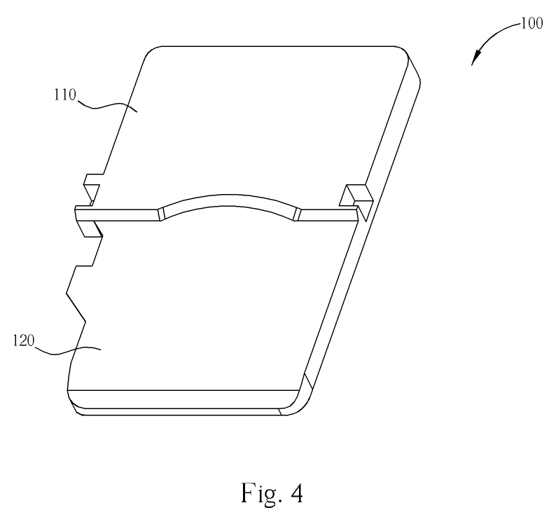

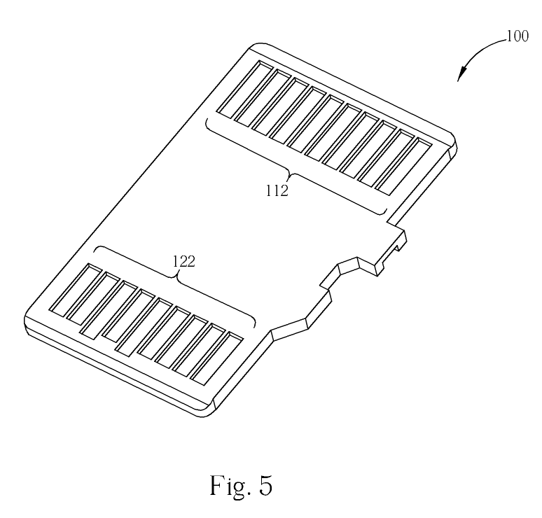

Please refer to FIGS. 4 and 5. FIG. 4 is a perspective front view of the multiple mode micro memory card 100. As shown, the first housing 110 has a greater thickness and a larger width than that of the second housing 120. This is due to the different dimensions of the MMCmicro memory card and microSD memory card form factors. FIG. 5 is a perspective rear view of the multiple mode micro memory card 100. The first housing 110 contains a set of ten first contact pads 112 and the second housing 120 contains a set of eight second contact pads 122.

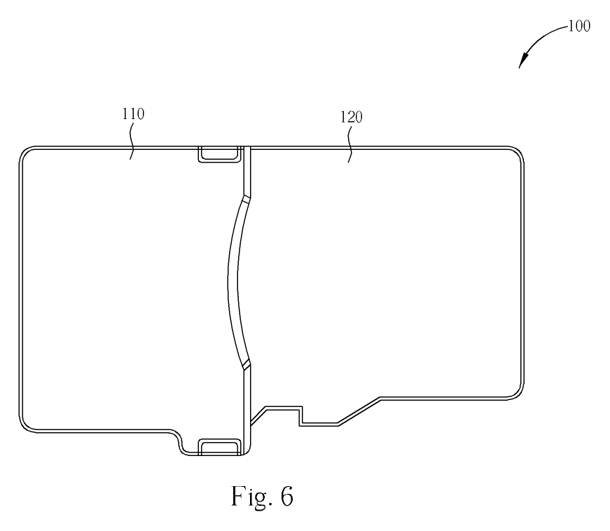

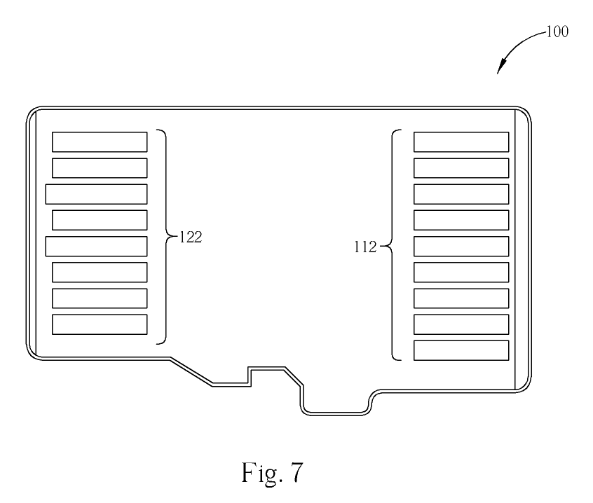

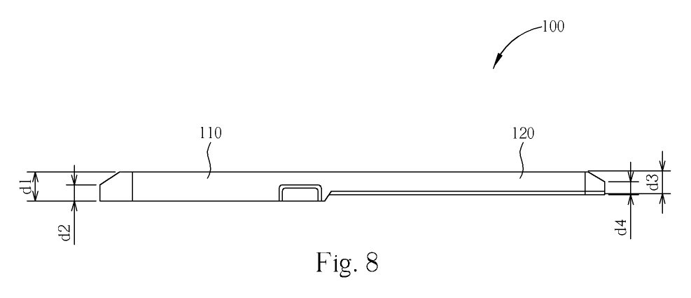

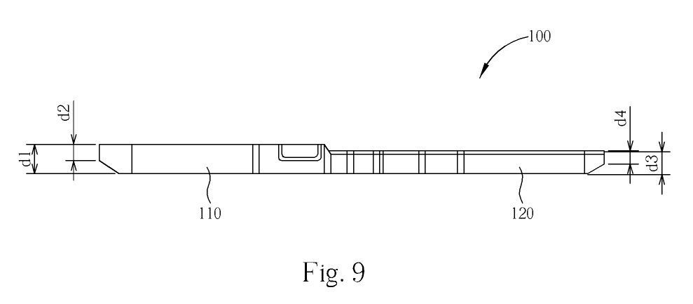

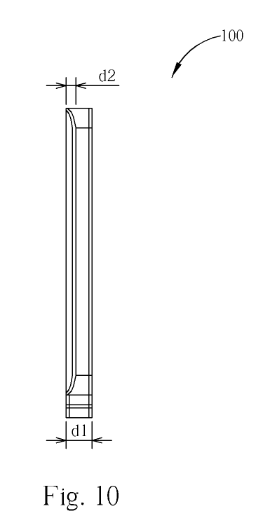

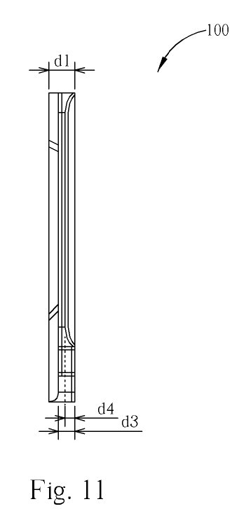

Please refer to FIGS. 6-11. FIG. 6 and FIG. 7 are front and rear views of the multiple mode micro memory card 100, respectively. FIG. 8 is a view of the top edge of the multiple mode micro memory card 100 as shown in FIG. 6, and FIG. 9 is a view of the bottom edge of the multiple mode micro memory card 100 as shown in FIG. 6. As shown in FIGS. 8 and 9, the first housing 110 has a first thickness d1 that tapers off to a second thickness d2 at the edge of the first housing 110. Likewise, the second housing 120 has a third thickness d3 that tapers off to a fourth thickness d4 at the edge of the second housing 120. The first thickness d1 is greater than the third thickness d3 since the thickness of the MMCmicro memory card standard is greater than the thickness of the microSD memory card standard. FIG. 10 and FIG. 11 are left and right side views of the multiple mode micro memory card 100 as shown in FIG. 6.

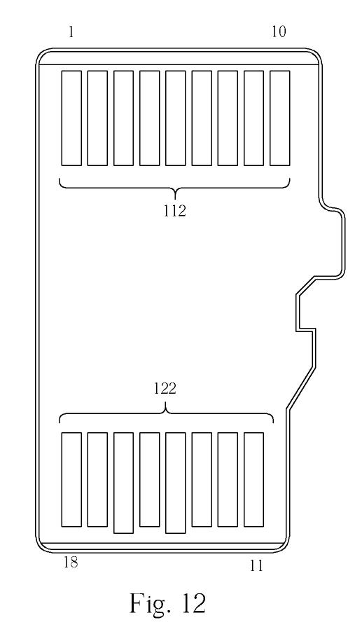

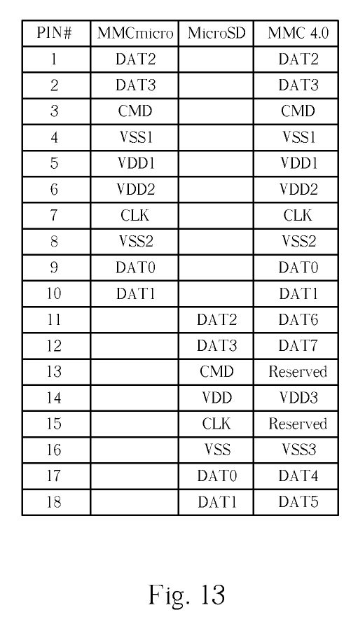

Please refer to FIG. 12 and FIG. 13. FIG. 12 is a rear view of the multiple mode micro memory card 100 showing pad numbers for the first contact pads 112 and the second contact pads 122. The first contact pads 112 are numbered from 1-10 and the second contact pads 122 are numbered from 11-18. FIG. 13 is a table describing the functions of contact pads on the multiple mode micro memory card 100 when the multiple mode micro memory card 100 is operated in different modes. When the multiple mode micro memory card 100 is operated according to either the MMCmicro memory card standard or the microSD memory card, a total of four data contact pads are used for reading and writing data. However, when both the first contact pads 112 and the second contact pads 122 are used, the multiple mode micro memory card 100 is able to conform to the MMC 4.0 standard, and is able to utilize 8 data contact pads. Therefore, the multiple mode micro memory card 100 provides the ability to have twice the data throughput if both the first contact pads 112 and the second contact pads 122 are used for reading or writing data.

In summary, the present invention multiple mode micro memory card 100 is compatible with both the MMCmicro memory card standard and the microSD memory card standard. In addition, the multiple mode micro memory card 100 can also be utilized in a new mode utilizing all 18 pins of the first contact pads 112 and the second contact pads 122 for doubling the data transfer rate by using 8 data pins instead of 4.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro memory card, comprising:
a first housing having a first thickness and a first width;
a first device connector formed on an end of the first housing, the first device connector conforming to a first device connection standard and allowing access to memory of the micro memory card by a device compatible with the first device connection standard;
a second housing having a second thickness and a second width different from the first thickness and the first width of the first housing, the second housing being integrally joined with the first housing; and
a second device connector formed on an end of the second housing at an opposite end of the micro memory card from the first device connector, the second device connector conforming to a second device connection standard and allowing access to memory of the micro memory card by a device compatible with the second device connection standard.

2. The micro memory card of claim 1, wherein the first device connector comprises a plurality of first contact pads and the second device connector comprises a plurality of second contact pads.

3. The micro memory card of claim 2, wherein the first device connector comprises ten first contact pads and the second device connector comprises eight second contact pads.

4. The micro memory card of claim 2, wherein the first device connection standard is a MMCmicro standard and the second device connection is a microSD standard.
